(19) United States
(12) Patent Application Publication
(10) Pub. No.: US 2013/0088806 A1
(43) Pub. Date: Apr. 11, 2013

(54) CONDUCTING MEMBER AND ELECTRONIC DEVICE

(71) Applicants: PING LI, Shenzhen City (CN); BAO-GANG ZHAO, Shenzhen City (CN); YUAN-MING WANG, Shenzhen City (CN); XUE-FENG WAN, Shenzhen City (CN)

(72) Inventors: PING LI, Shenzhen City (CN); BAO-GANG ZHAO, Shenzhen City (CN); YUAN-MING WANG, Shenzhen City (CN); XUE-FENG WAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/527,797

(22) Filed: Jun. 20, 2012

(30) Foreign Application Priority Data
Oct. 6, 2011 (CN) 201110292890.4

(51) Int. Cl. H05F 3/00; H05K 7/00

(52) U.S. Cl. 361/220; 361/679.01

(57) ABSTRACT

An electronic device includes a housing, an electronic member received in the housing, a conduction plate secured to the housing and grounded, and a conducting member connecting with the elastic member with the conduction plate to conduct static electricity in the electronic member to the conduction plate. The conducting member includes a base portion. A first elastic sheet and a second elastic sheet are secured to and respectively protrude out of opposite surfaces of the base portion. The first and second elastic sheets elastically contact with the conduction plate and the electronic member respectively. A conducting member of an electronic device is also provided.

### BACKGROUND

1. Technical Field

The present disclosure relates to electronic devices, and more particularly to an electronic device having a conducting member for conducting static electricity.

2. Description of Related Art

Electronic devices, such as DVD players, include a circuit board, a conduction plate, which are grounded, and a conducting member. The conducting member connects the circuit board with the conduction plate, such that static electricity in the electronic member can be conducted through the conduction plate grounded.

The conducting member is typically fixed to the circuit board with a free elastic arm abutting the conduction plate. However, the free elastic arm is supported alone by the conduction plate, and may sometimes make incomplete contact with the conduction plate, such that static electricity in the circuit board may not be grounded.

Therefore, there is room for improvement in the art.

### BRIEF DESCRIPTION OF THE DRAWINGS

The components of the drawings are not necessarily drawn to scale, the emphasis instead being placed upon clearly illustrating the principles of the embodiments of the electronic device. Moreover, in the drawings, like reference numerals designate corresponding parts throughout several views.

FIG. 1 is a partial perspective view of an electronic device in accordance with one embodiment.

FIG. 2 is a partially disassembled view of the electronic device in FIG. 1; the electronic device including a conducting member.

FIG. 3 is a perspective view of the conducting member in FIG. 2.

FIG. 4 is cross-sectional view taken along line IV-IV of FIG. 1.

### DETAILED DESCRIPTION

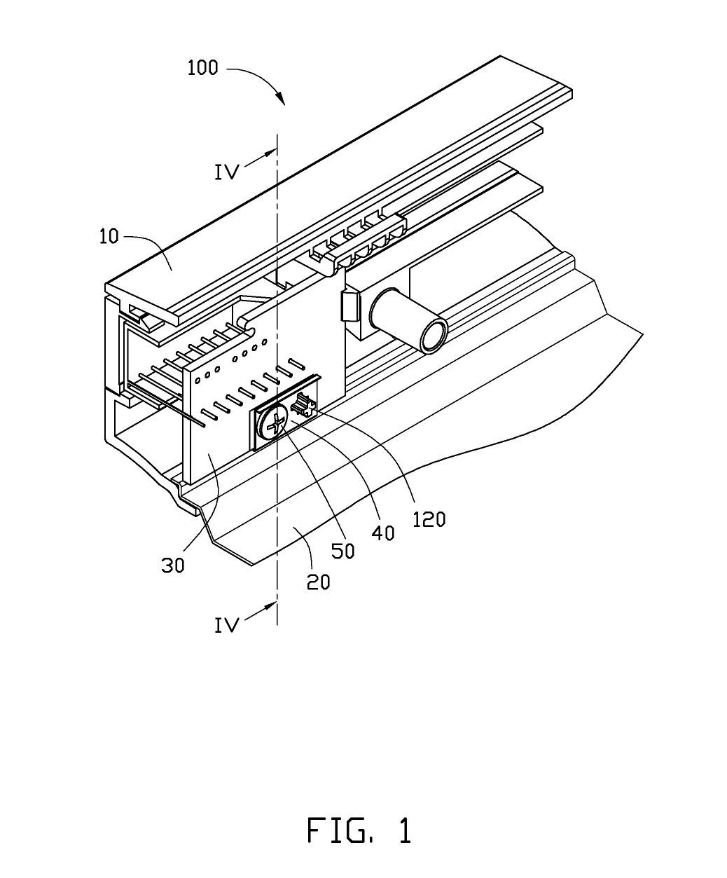

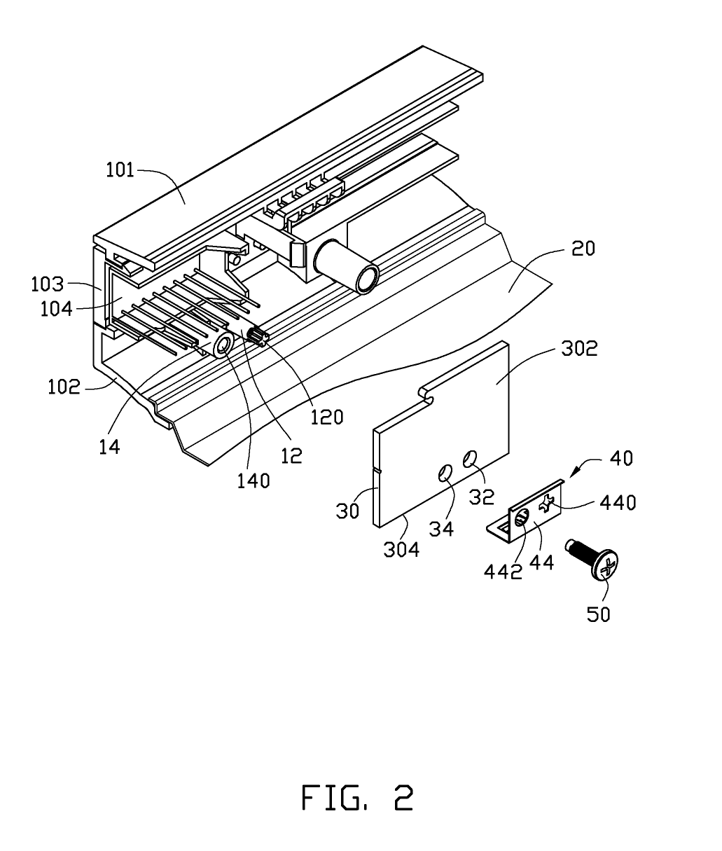

FIGS. 1-2, is an electronic device 100 of the present disclosure. The electronic device 100 includes a housing 10, a conduction plate 20 secured to the housing 10 and grounded, an electronic member 30 received in the housing 10, and a conducting member 40. The conduction plate 20 is grounded. The conducting member 40 connects the electronic component 30 with the conduction plate 20, such that static electricity in the electronic member 30 can be conducted directly to the conduction plate 20.

The housing 10 includes a top wall 101, a bottom wall 102 and a plurality of sidewalls. The top wall 101, the bottom wall 102 and the sidewalls cooperatively define a receiving space 104 for receiving the electronic member 30, the conducting member 40 and other electronic components (not shown) of the electronic device 100. A limiting post 12 and a fixing post 14 perpendicularly protrude from an inner surface of one of the sidewalls (referred to herein as the first sidewall 103). The limiting post 12 and the fixing post 14 are spaced from each other. A limiting member 120 is secured to an end of the limiting post 12 away from the first sidewall 103. The cross section of the limiting member 120 is substantially orthogonal cross-shaped. The fixing post 14 defines a fixing hole 140 for threading a fixing member, such as a screw 50.

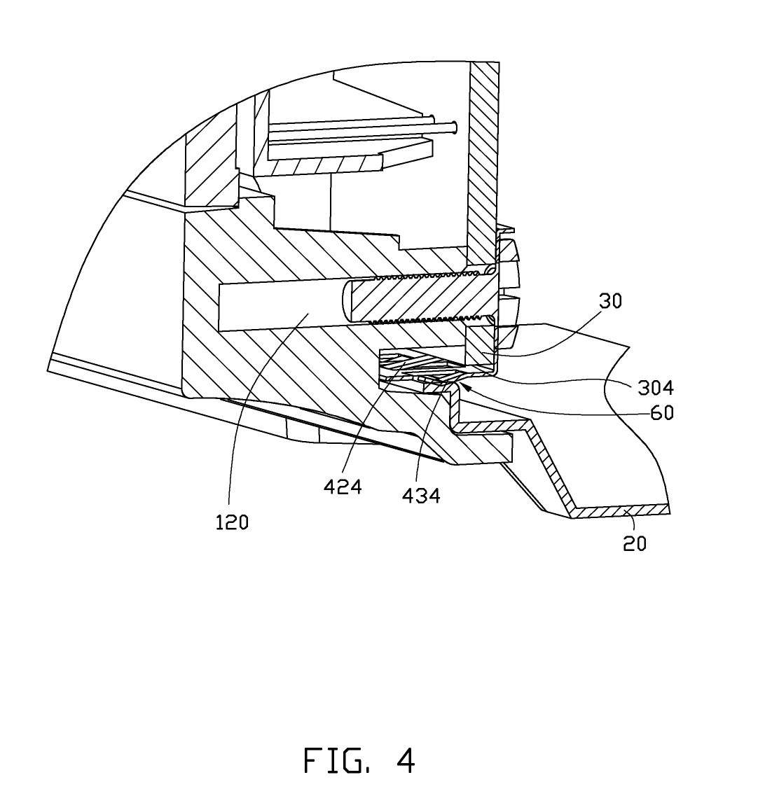

The conduction plate 20 is grounded, and is made of metal, such as copper. The conduction plate 20 is secured to the bottom wall 102. The conduction plate 20 is spaced from the electronic member 30 to define a clipping space 60 (see FIG. 4). In other embodiments, the conduction plate 20 may be a portion of the bottom wall 102.

The electronic member 30 is a circuit board of the electronic device 100 in the embodiment. The electronic member 30 is secured to the housing 10 by means of the limiting post 12 and the fixing post 14. The electronic member 30 is substantially rectangular, and is parallel to the first sidewall 103. The electronic member 30 includes a first surface 302 opposite to the first sidewall 103 and an end portion 304 connecting with the first surface 302 and facing the bottom wall 102. The first surface 302 defines two round holes 32, 34. The round hole 32 corresponds to the limiting post 12. The size of the round hole 32 is slightly greater than the diameter of the limiting post 12, such that the limiting post 12 is fitted in the round hole 32. The round hole 34 corresponds to the fixing hole 140, and the size of the round hole 34 is substantially equal to the fixing hole 140.

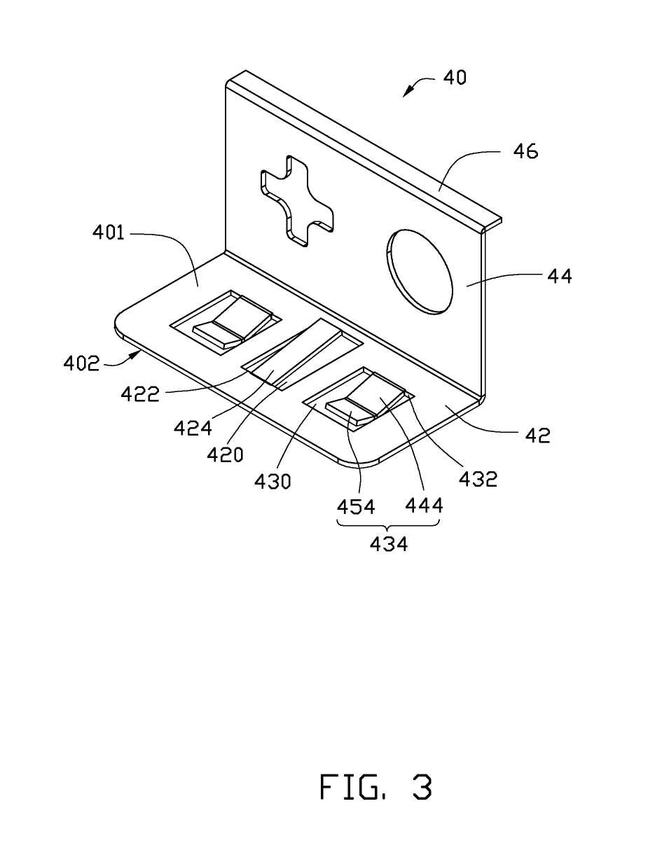

Referring to FIG. 3, the conducting member 40 is made of metal and is capable of being elastically deformed. The conducting member 40 includes a base portion 42, a fixing portion 44, and a stopper 46. The base portion 42 and the stopper 46 are substantially perpendicular to the fixing portion 44, and respectively extend from opposite sides of the fixing portion 44 in opposite directions. The stopper 46 prevents the conducting member 40 from being installed in reverse.

The base portion 42 is substantially rectangular. The base portion 42 defines three through holes (hereinafter, a first through hole 420 and two second through holes 430). The first through hole 420 is between the two second through holes 430. Each through hole 420,430 have a first edge 422 and a second edge 432 opposite to and parallel with the first edge 422. In the embodiment, the first and second edges 422/432 are parallel to the fixing portion 44, and the second edge 432 is between the first edge 422 and the fixing portion 44.

A first elastic sheet 424 is secured to the first edge 422 of the first through hole 420, and the free end of the first elastic sheet 424 protrudes out of a top surface 401 of the base portion 42 in a first direction which is facing the fixing portion 44. The first elastic sheet 424 is elastically deformed to be received in the elongated hole 420 when being pressed. In the embodiment, the first elastic sheet 424 integrally extends from the base portion 42.

Two second elastic sheets 434 are respectively secured to the second edges 432 of the second through holes 430. Each second elastic sheet 434 is substantially V-shaped, and includes a connecting portion 444 and an abutting portion 454. The connecting portion 444 is secured to the second edge 432 and protrudes out of a bottom surface 402 of the base portion 42 in a second direction, which is away from the fixing portion 44. The abutting portion 454 bends from an end of the connecting portion 444 away from the second edge 432. In the embodiment, the abutting portion 454 protrudes out of the bottom surface 402 when the second elastic sheet 434 is in an original state.

The fixing portion 44 is perpendicularly bent from a rim of the base portion 42. The fixing portion 44 defines a limiting hole 440 and a receiving hole 442 spaced from the limiting hole 440. The limiting hole 440 is substantially cross-shaped, and corresponds to the limiting portion 120. The limiting hole 440 is configured to receive the limiting portion 120 and to prevent the conducting member 40 from rotating relative to the limiting post 12. The receiving hole 442 is substantially round, and corresponds to the fixing post 14.

Referring to FIGS. 1 and 4, in assembly, first, the limiting post 12 is received in the round hole 32. Second, the base portion 42 of the conducting member 40 is received in the clipping space 60 with the first elastic sheet 424 abutting the electronic member 30 and the second elastic sheets 434 abutting the conduction plate 20, and the limiting portion 120 is received in the limiting hole 440. Finally, the receiving hole 442 and the round hole 34 are aligned with the fixing hole 140, and the fixing member 50 extends through the receiving hole 442 and the round hole 34 to be threaded into the fixing hole 140.

Referring again to FIG. 4, after assembly, the base portion 42 is clipped between the elastic member 30 and the conduction plate 20. The first elastic sheet 424 elastically abuts the electronic member 30. The second elastic sheets 434 elastically abut the conduction plate 20, thus, the conducting member 40 retains to contact with the electronic member 30 and the conduction plate 20, and static electricity in the electronic member 30 can be conducted directly to the conduction plate 20 and further grounded.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An electronic device, comprising:
a housing;
an electronic member received in the housing;
a conduction plate secured to the housing and being grounded; and
a conducting member connecting with the elastic member and the conduction plate to conduct static electricity in the electronic member to the conduction plate and further grounded, the conducting member comprising a base portion being clipped between the elastic member and the conduction plate;
wherein at least one first elastic sheet and at least one second elastic sheet are secured to and respectively protrude out of opposite surfaces of the base portion, the at least one first elastic sheet and the at least one second elastic sheet elastically contact with the conduction plate and the electronic member respectively.

2. The electronic device of claim 1, wherein the conducting member further comprises a fixing portion, the fixing portion bents from a rim of the base portion and is secured to the electronic member.

3. The electronic device of claim 1, wherein the base portion defines at least two through holes, each through hole has a first edge and a second edge opposite to the first edge, the at least one first elastic sheet is secured to the first edge with a free end protruding out of a top surface of the base portion.

4. The electronic device of claim 3, wherein the at least one second elastic sheet is secured to the second edge of the at least one through hole and protrudes out of a bottom surface of the base portion opposite to the top surface.

5. The electronic device of claim 4, wherein each the second elastic sheet comprises a connecting portion and an abutting portion, the connecting portion extends from the second edge, the abutting portion bents from an end of the connecting portion away from the second edge and protrudes out of the bottom surface of the base portion.

6. The electronic device of claim 2, wherein the conducting member further comprises a stopper, the stopper bents from a rim of the fixing portion away from the base portion and extends opposite to the base portion.

7. The electronic device of claim 2, wherein the housing comprises a first sidewall and a bottom wall connecting with the first sidewall, a fixing post and a limiting post protrude from an inner surface of the first sidewall, the fixing post defines a fixing hole, and a limiting portion is secured to an end of the limiting post away from the first sidewall.

8. The electronic device of claim 7, wherein the electronic member defines two round holes, one of the round holes corresponds to the fixing hole, and the other of the round holes corresponds to and receives the limiting post.

9. The electronic device of claim 8, wherein the fixing portion defines a receiving hole corresponding to the fixing hole and a limiting hole for receiving the limiting portion.

10. The electronic device of claim 9, wherein the limiting hole is fitted to the limiting portion to prevent the fixing portion from rotating relative to the limiting post.

11. A conducting member of an electronic device, the electronic device comprising an electronic member and a conduction member being grounded, the conduction member for conducting static electricity in the electronic member, the conduction member comprising:
a base portion being clipped between the elastic member and the conduction plate; and
a fixing portion bending from a rim of the base portion and secured to the electronic member;
wherein at least one first elastic sheet and at least one second elastic sheet are secured to and respectively protrude out of opposite surfaces of the base portion, the at least one first elastic sheet and the at least one second elastic sheet elastically contact with the conduction plate and the electronic member respectively.

12. The conducting member of claim 11, wherein the base portion defines at least two through holes, each through hole has a first edge and a second edge opposite to the first edge, the at least one first elastic sheet is secured to the first edge with a free end protruding out of a top surface of the base portion.

13. The conducting member of claim 12, wherein the at least one second elastic sheet is secured to the second edge of the at least one through hole and protrudes out of a bottom surface of the base portion opposite to the top surface.

14. The conducting member of claim 13, wherein each the second elastic sheet comprises a connecting portion and an abutting portion, the connecting portion extends from the second edge, the abutting portion bents from an end of the connecting portion away from the second edge and protrudes out of the bottom surface of the base portion.

15. The conducting member of claim 11, further comprising a stopper, wherein the stopper bents from a rim of the fixing portion away from the base portion and extends opposite to the base portion.

16. The conducting member of claim 11, wherein the electronic device comprises a first sidewall and a bottom wall connecting with the first sidewall, a fixing post and a limiting post protrude from an inner surface of the first sidewall, the fixing post defines a fixing hole, and a limiting portion is secured to an end of the limiting post away from the first sidewall.

17. The conducting member of claim 16, wherein the electronic member defines two round holes, one of the round holes corresponds to the fixing hole, and the other of the round holes corresponds to and receives the limiting post.

18. The conducting member of claim 17, wherein the fixing portion defines a receiving hole corresponding to the fixing hole and a limiting hole for receiving the limiting portion.

19. The conducting member of claim 18, wherein the limiting hole is fitted to the limiting portion for preventing the fixing portion from rotating relative to the limiting post.
